(19) United States
(12) Patent Application Publication
(10) Pub. No.: US 2008/0251916 A1
(43) Pub. Date: Oct. 16, 2008

(54) UBM structure for strengthening solder bumps

(75) Inventors: CHIU SUNG CHENG, Jhubei City (TW); HSIU-MEI YU, Hsinchu (TW); CHIA-JEN CHENG, Taoyuan City (TW); C.T. CHUANG, Chiayi City (TW); CHUN-YEN LO, Hsin-Chu (TW); LI-HSIN TSENG, Jhubei City (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsinchu (TW)

(21) Appl. No.: 11/734,483

(22) Filed: Apr. 12, 2007

(51) Int. Cl. H01L 23/488; H01L 21/44

(52) U.S. Cl. 257/738; 257/761; 438/614; 257/E23.023; 257/E21.476

(57) ABSTRACT

A novel UBM structure for improving the strength and performance of individual UBM layers in a UBM structure is disclosed. In one aspect, a UBM structure for disposal onto an electrically conductive element comprised of aluminum is disclosed. In one embodiment, the UBM structure comprises a tantalum layer disposed over the aluminum electrically conductive element, and a copper layer disposed over the tantalum layer, where the UBM structure is configured to receive a solder ball thereon.

### TECHNICAL FIELD

Disclosed embodiments herein relate generally to semiconductor wafer processing, and more particularly to improved under-bump metallization (UBM) structures and associated methods for strengthening solder bump.

### BACKGROUND

UBM structures are often utilized during semiconductor manufacturing processes. Semiconductor manufacturing processes generally begin with processes associated with fabricating a semiconductor wafer such as layering, patterning, doping, and heat treatments. Once fabricated, semiconductor wafers undergo additional processes associated with testing, packaging, and assembling semiconductor IC chips obtained from the wafers. Semiconductor manufacturing processes are continually being refined, modified, and improved in light of breakthroughs in semiconductor technology. One such technology that has continued to gain increased acceptance is “flip chip” technology, which refers to microelectronic assemblies in which direct electrical connections between face down, or flipped, chip components and outside components (e.g. substrates) are achieved through conductive bump or bonding pads formed on the chip.

Conventional bonding pads in flip chip applications are typically manufactured to include a final metal layer, such as aluminum, to facilitate electrical communication from the IC chip. Flip chips are also manufactured to include solder bumps, which are deposited onto the bonding pads of such chips to physically and electrically connect the bonding pads with electrode terminals provided on packaging such as ceramic substrates, printed circuit boards, or carriers. Solder bumps are typically formed of a metal alloy such as a lead-tin alloy, and are often applied to semiconductor wafers prior to separation into individual semiconductor chips.

Solder bumps, however, are generally not applied directly to the bonding pads of the semiconductor wafer. It has been found that the direct application of solder bump material to the semiconductor wafer yields poor electrical conduction, due largely to the rapid oxidation of the final metal layer (e.g. aluminum) upon exposure to air. Moreover, aluminum has been found to be neither particularly wettable nor bondable with most solders. Accordingly, UBM structures and associated techniques have been developed to provide a low resistance electrical connection between the solder bump and the underlying bonding pad, while attempting to withstand the various stresses associated with semiconductor applications.

UBM structures generally include one or more metallic layers, such as layers of titanium/copper (Ti/Cu), deposited over the bonding pads of IC chips. In practice, solder is typically deposited over a UBM structure, and then heated via a reflow process to form a generally spherical solder bump. It has been found that prior art UBM structures tend to experience poor reliability and performance when solder material comes in contact with copper of the UBM structure during the solder bump formation process. More particularly, the interface of copper with solder during the soldering process may generate a variety of interfacial reactions, such as dissolution of copper into the solder, formation of intermetallic compounds, and oxidation of the copper layer. These reactions are generally undesirable as they weaken the bond between the solder bump and the bonding pad of the chip, thereby leading to premature failure of the chip. For example, some chips in which these reactions have been observed have been found to fail after 1000 hours of high temperature storage.

Another type of failure that is often experienced with conventional UBM structures is the delamination of the UBM structure, which is the separation of layers in the UBM structure, under strict reliability testing conditions, for example, testing conditions having a temperature range of −65° C. to 150° C., with a testing increment of about 1000 times. As mentioned above, the typical multi-layer construction for a UBM structure is a lower layer of titanium, with a layer of copper formed over it. The titanium is formed first and in direct contact with the bonding pad of the chip because titanium adheres well to aluminum. In some cases, nickel may also be formed over the copper layer as well, since nickel adheres well to many of the typical types of solder used to form the solder balls on the UBM structure. Unfortunately, under high stress conditions, delamination can occur between the titanium and copper layers, often detrimentally affecting device structure (i.e., strength) and performance.

FIG. 1 illustrates an exemplary conventional solder bump arrangement in which a solder bump 10 has been formed over an aluminum bonding pad 12 of an IC chip 14. A plurality of UBM layers 16A, 16B, 16C have been formed between the resulting solder bump 10 and the bonding pad 12. In this example, the UBM layer 16A is a layer of titanium, UBM layer 16B is copper, and UBM layer 16C is nickel. The UBM layers 16A, 16B, 16C are formed such that their perimeter edges are substantially flush with one another and are exposed to outside elements. A passivation layer 22 and a polyimide layer 24 have also been formed over the IC chip 14.

One the critical problems associated with this prior art solder bump arrangement relates to the delamination of some of the UBM layers. In particular, under high stress conditions, delamination between the titanium layer 16A, which is used because of its good adherence to the aluminum of the nodding pad 12, and the copper layer 16B, which is used because of it's good adherence to the nickel layer 16C or to the solder ball 10 itself if no nickel layer is desired. Accordingly, what is needed is a new UBM structure that does not suffer from delamination between UBM layers under high stress conditions, as often occurs in the prior art.

### BRIEF SUMMARY

A novel UBM structure for improving the strength and performance of individual UBM layers in a UBM structure is disclosed. In one aspect, a UBM structure for disposal onto an electrically conductive element comprised of aluminum is disclosed. In one embodiment, the UBM structure comprises a tantalum layer disposed over the aluminum electrically conductive element, and a copper layer disposed over the tantalum layer, where the UBM structure is configured to receive a solder ball thereon. In another aspect, a semiconductor device is disclosed. In one embodiment, the semiconductor comprises a semiconductor chip having an aluminum bonding pad formed on a semiconductor surface thereof, and a UBM structure formed over the bonding pad. The UBM structure comprises a first metallic layer formed of tantalum disposed adjacent to and in contact with the bonding pad, and a second metallic layer formed of copper disposed adjacent to and in contact with the first metallic layer. Perimeter portions of the first and second layers extend over another portion of the semiconductor device, such as a passivation layer.

Related methods of manufacturing a semiconductor device are also disclosed. In one embodiment, the method comprises providing a bonding pad associated with the semiconductor device, and depositing a tantalum layer over and in direct contact with the bonding pad. In addition, such a method comprises depositing a copper layer over and in direct contact with the tantalum layer, and depositing a third metallic layer over and in direct contact with the copper layer. Then, the method includes forming a solder bump over and in direct contact with the third metallic layer. Accordingly, practicing the method of the present disclosure avoids undesirable delamination be lower layers in a UBM structure.

### BRIEF DESCRIPTION OF THE DRAWINGS

Reference is now made to the following descriptions taken in conjunction with the accompanying drawings, in which:

FIG. 1 illustrates a sectional view of a semiconductor chip having undergone a prior art solder bump formation process.

FIG. 2 illustrates a general block diagram of one embodiment of a process associated with manufacturing IC chips having UBM structures according to the disclosed principles; and

FIGS. 3A-3E illustrate sectional views of an exemplary process for forming a UBM structure and associated solder bump on an individual chip in accordance with the disclosed principles.

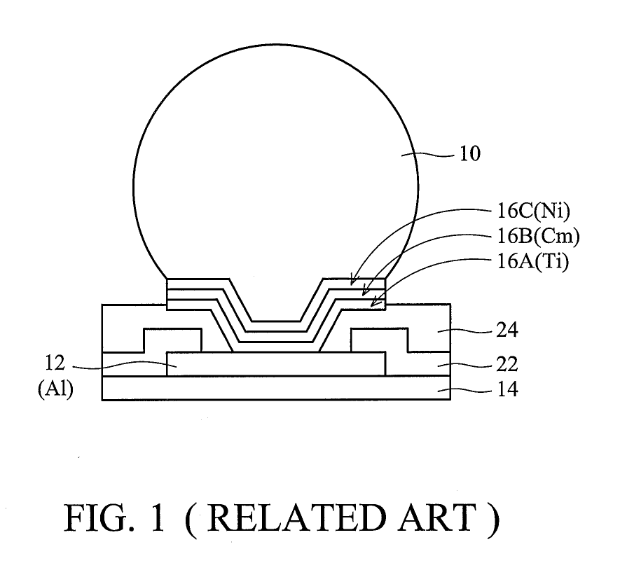

### DETAILED DESCRIPTION

UBM structures may be utilized in any arrangement requiring bonding between electrically conductive components. By way of example, UBM structures are often utilized in the manufacture of semiconductor devices. Although this disclosure describes unique UBM structures in the context of implementation into semiconductor devices, it is contemplated that the UBM structures of the present disclosure may be incorporated into devices other than semiconductor devices.

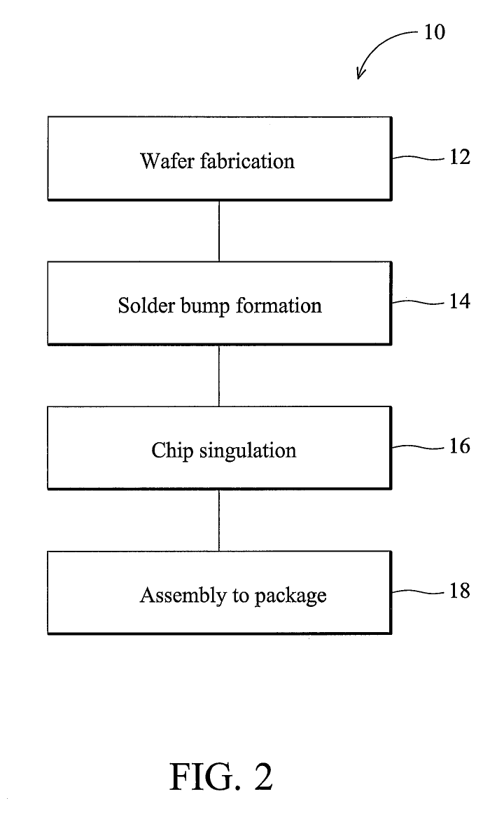

FIG. 2 is a block diagram illustrating an exemplary semiconductor manufacturing process 11 associated with producing chips for use in semiconductor applications. The process 11 includes wafer fabrication 13, which generally involves layering, patterning, doping, and applying heat treatments to a silicon wafer. The process 11 further includes forming solder bumps 15 on the fabricated wafer. The solder bumps generally facilitate electrical and mechanical connection, for example, in flip chip applications, between chip devices singulated from the fabricated wafer and a desired packaging substrate as will be further described. The fabricated wafer is then cut into singulated chips 17 each comprising an entire integrated circuit. After singulation, the chips are assembled 19 with desired packaging to complete the manufacturing process.

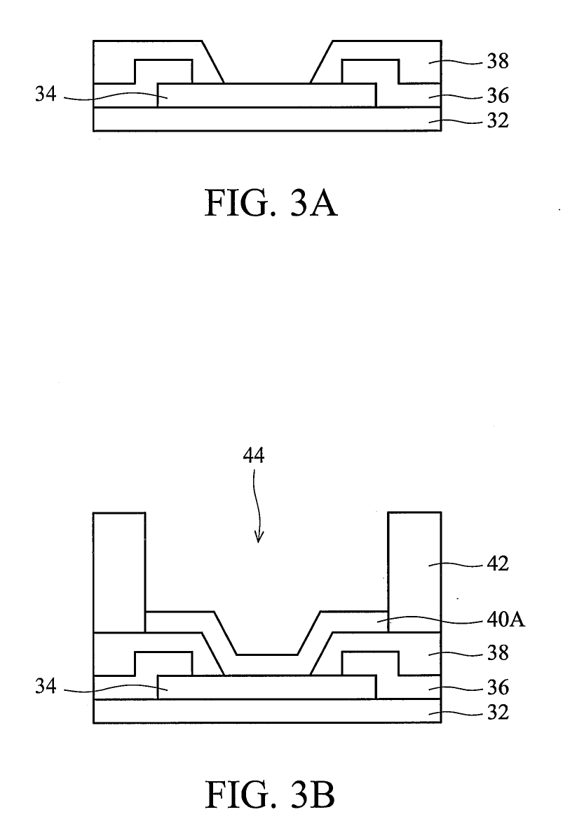

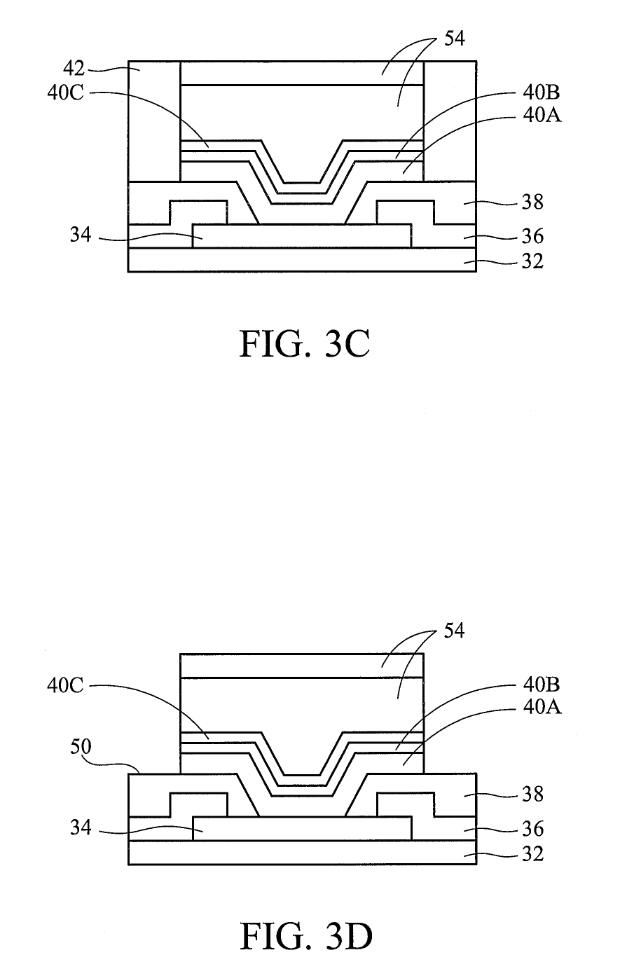

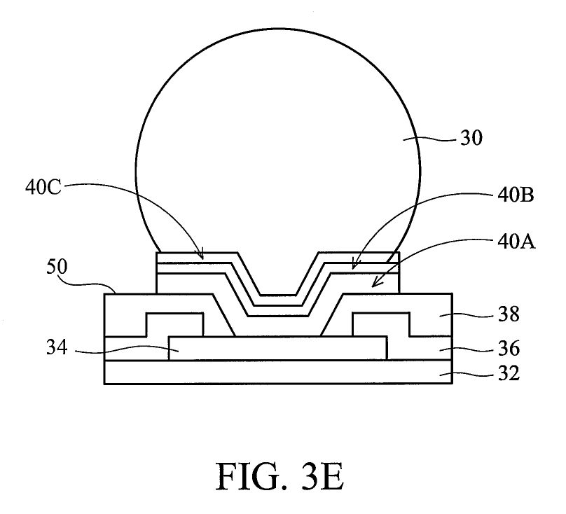

Each of the above-described processes may be carried out in a variety of ways. The following disclosure relates to particular manners for carrying out the solder bump formation process 15, and more particularly, ways for forming a UBM structure associated with the solder bump formation process 15. FIGS. 3A-3E illustrate one exemplary process for forming a novel UBM structure for receiving a solder bump 30 (FIG. 3E), where the UBM structure resists delamination between layers in the UBM structure. The solder bump 30 may be formed of a metallic alloy such as a lead-tin alloy. In some embodiments, the solder bump 30 may be formed as part of a larger C4 process (Controlled-Collapse Chip Connection), which connects semiconductor chips, such as chip 32, to substrates in electronic packages.

The chip 32 is manufactured to include a plurality of bonding pads 34, one of which is shown in FIG. 3A. The bonding pad 34 is a source of electrical communication from the chip 32, and typically comprises aluminum (Al) with patterned levels of interconnecting metal lines. For example, signal lines and power/ground lines can be connected to the bonding pad 34. The bonding pad 34 may be formed in a variety of manners such as through vapor deposition techniques.

After the bonding pad 34 is formed, a passivation layer 36 is formed over the semiconductor chip 32 surface excluding a portion overlying the bonding pad. The passivation layer 36 may be vapor deposited over the chip 32 to generally insulate and protect the surface of the chip 32 from moisture and other contaminants and also from mechanical damage during assembling of the chip. The passivation layer 36 may be formed of a variety of materials, such as silicon oxide/silicon nitride (SiO₂/Si₃N₄) or phosphorous doped silicon dioxide. Various types of photosensitive polyimides may also be deposited as a polyimide layer 38 over the passivation layer 36 to further protect the chip 32.

Referring to FIG. 3B, a first under-bump metallization (UBM) layer 40A may then be deposited over the bonding pad 34. More specifically, UBM layer 40A is formed first over the polymide layer 38 and in contact with the bonding pad 34. UBM layers are typically formed over the bonding pad 34 to allow for better bonding and wetting of the solder material to an uppermost UBM layer adjacent to the solder material, and for protection of the bonding pad 34 by a lowermost UBM layer, such as UBM layer 40A.

In a preferred embodiment, the UBM layer 40A may be about 1 micron in height and is formed of tantalum (Ta) rather than the usual titanium (Ti) used in conventional techniques. In a specific embodiment, the first layer 40A is formed by a sputter deposition of tantalum on the bonding pad 34. An exemplary solution discovered to pattern the tantalum onto the bonding pad 34 is an etching solution comprising about 30% HF and 70% HNO₃. Of course, any other etching solution that is suitable for patterning tantalum layer 40A onto the bonding pad 34 may also be employed.

As discussed above, while older conventional UBM structures used a copper layer formed directly on the bonding pad, more modern conventional UBM structures employ titanium directly in contact with the bonding pad, and then form a copper layer over the titanium layer. The use of the titanium layer improves the adherence of the UBM structure to the bonding pad, which thus improves overall solder ball structure strength and reliability. As a result, substantially all current UBM structures employ a titanium first layer as a relatively inexpensive means for improving adherence of the UBM structure to the bonding pad. However, while improving this adherence, a disadvantage to use of the titanium layer between the copper layer and the bonding pad is that under high stress situations, delamination between that titanium layer and the copper layer often occurs.

To solve this problems and to thus provide a UBM structure that can withstand higher stress conditions than conventional UBM structures employing titanium first layers, the disclosed technique eliminates this popular titanium layer and deposits a tantalum layer 40A directly on the bonding pad 34. A copper layer 40B is then formed over the tantalum layer 40A, as shown in FIG. 3B, and may have a thickness of about 5 microns. Next, although not required, a third layer 40C may be formed over the copper layer 40B. This third layer 40C may be comprised of a material that has an improved adherence to the later-formed solder ball when compared to the basic copper layer 40B. In exemplary embodiments, this third layer 40C may be formed from nickel, which is know to have excellent adherence to both copper and typical lead-tin based composition of solder balls.

By employing tantalum rather than titanium as the first layer 40A between the bonding pad 34 and the copper layer 40B, the possibility of delamination between the first and second layers 40A, 40B is significantly decreased in the face of high stress conditions. Accordingly, the disclosed technique is based on the recognition of tantalum's improved adherence characteristics with respect to both the aluminum of the bonding pad 34 and the copper of the second layer 40B, when it is compared to the conventional use of titanium as the first layer. For example, testing of UBM structures manufactured in accordance with the presently disclosed principles have shown a tensile stress level of 10E9 between the tantalum-copper layers 40A, 40B, versus a higher tensile stress level of 10E10 between the conventionally formed titanium-copper UBM layers typically employed.

It should also be noted that tantalum is significantly more expensive than titanium, currently about 3 times higher. Typically, tantalum is used in advance IC technology, such as 0.13 um and 90 nm manufacturing process. Moreover, titanium is easily etched with HF; however, tantalum typically requires a HF/HNO3 solution for complete removal. Thus, in view of these process obstacles, although it would not be obvious for persons in the field of the present disclosure to employ tantalum in a UBM structure, the advantages of tantalum's adherence, as discussed above, is recognized by the present disclosure as outweighing these obstacles.

Looking now at FIG. 3C, once the novel UMB layers 40A, 40B and 40C disclosed herein have been formed over the bonding pad 34, a layer of photoresist 42 is formed over the UBM layers 40A, 40B, 40C. The photoresist layer 42 is typically from about 10 to about 25 microns in height. As shown in FIG. 3C, the photoresist layer 42 is photolithographically patterned and developed to form an opening 44 above the bonding pad 34. Within the opening 44, a column of solder material 54 may either be deposited in layers, for example, a layer of lead followed by a layer of tin, or may be formed as a single layer. If multiple layers are deposited, the solder material layers are later formed into a homogeneous solder bump during a reflow (e.g., temporary melting) process for solder material. In other embodiments, the solder material may be deposited as a homogeneous solder material by vapor deposition or electroplating onto a “seed” layer. In the illustrated embodiment, the seed layer is the nickel layer 40C formed over the copper layer 40B.

Referring to FIG. 3D, after removal of the photoresist layer 42, the solder column 54 is used as a mask to etch the final width of the UMB layers 40A, 40B and 40C. Once the widths of all of the UMB layers 40A, 40B, 40C are finalized, the solder column 54 is temporarily heated to a melting point in a reflow process to form the solder bump 30 over the UBM structure (layers 40A, 40B, 40C). Completion of the reflow process results in the formation of the homogeneous lead/tin solder bump 30, which is illustrated in FIG. 3E. In some embodiments, the solder bump 30 is a high lead alloy having composition ratios (indicating weight percent) of 95 Pb/5 Sn (95/5) or 90 Pb/10 Sn (90/10) with melting temperatures in excess of 300° C. or eutectic 63 Pb/37 Sn (63/37) with a melting temperature of 183° C. Generally speaking, the resulting solder bump 30 is composed of a homogeneous material and has a well-defined melting temperature. The high melting Pb/Sn alloys are reliable bump metallurgies that are particularly resistant to material fatigue.

The above-described process for forming the solder bump 30 is merely exemplary. Accordingly, the solder bump 30 may be formed in a variety of other manners, including processes other than photoresist processes, without departing from the scope of the disclosure. Also, FIGS. 3A-3E are schematic depictions of the chip 32 and associated structure, and therefore, should not be construed to limit the such structure to any particular geometric orientation. Additionally, the geometric orientations of the UBM layers 40A, 40B, 40C and the passivation and polyimide layers 36 and 38, respectively, may also be altered to have different shapes. Accordingly, these layers may take flat (uniform in cross-section) or non-flat (non-uniform in cross-section) configurations.

Still further, although the UBM layer 40C is described as being formed of nickel, various other materials may be used in the formation of UBM layer 40C. Moreover, the overall chip/bump structure has been described as having certain types of layers. However, layers such as the passivation layer 36 and the polyimide layer 38 may be altered or even removed without departing from the scope of the disclosure. Additional UBM layers may be provided so long as the tantalum layer 40A is deposited directly on the bonding pad 34, and the copper layer 40B is deposited on the tantalum layer 40A. By selecting tantalum for the first layer 40A rather than the typical titanium, delamination between the first layer 40A and the second layer 40B may be significantly decreased when the chip is subjected to high stress conditions.

While various UBM structures and related methods for forming UBM structures during the solder bump formation process according to the principles disclosed herein have been described above, it should be understood that they have been presented by way of example only, and not limitation. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

1. A UBM structure for disposal onto an electrically conductive element comprised of aluminum, the UBM structure comprising:
at least one insulation layer formed over a perimeter of an aluminum electrically conductive element in direct electrical contact with an underlying integrated circuit, the at least one insulation layer leaving a center portion of the electrically conductive element exposed;
a tantalum layer disposed over the at least one insulation layer and the exposed center portion of the aluminum electrically conductive element, the tantalum layer dipping down from the at least one insulation layer to directly contact the center portion; and
a copper layer disposed over the tantalum layer and having substantially the same curvature of the tantalum layer, the UBM structure having a cup shaped configured to receive a solder ball thereon.

2. The UBM structure of claim 1, further comprising a third metallic layer disposed on the copper layer and having substantially the same curvature as the copper and tantalum layers, and configured to receive the solder ball within its curvature.

3. The UBM structure of claim 2, wherein the third metallic layer is formed of nickel.

4. The UBM structure of claim 1, wherein the electrically conductive element and the UBM structure are associated with a semiconductor device.

5. The UBM structure of claim 4, wherein the electrically conductive element is a bonding pad formed on a semiconductor chip of the semiconductor device.

6. The UBM structure of claim 15, wherein the at least one insulation layer comprises a passivation layer.

7. The UBM structure of claim 6, wherein the at least one insulation layer further comprises a polyimide layer disposed adjacent to and in contact with the passivation layer and the bonding pad.

8. The UBM structure of claim 1, wherein the tantalum layer is about 1 micron in height.

9. The UBM structure of claim 1, wherein the copper layer is about 5 microns in height.

10. A semiconductor device, comprising:
a semiconductor chip having an aluminum bonding pad formed on a semiconductor surface thereof, the aluminum bonding pad in direct electrical contact with an integrated circuit:
at least one insulation layer formed over a perimeter of the aluminum bonding pad so as to leave a center portion of the bonding pad exposed; and
a UBM structure formed over the bonding pad, the UBM structure comprising a first metallic layer formed of tantalum disposed over the at least one insulation layer, and adjacent to and in contact with the center portion of the bonding pad, the UBM structure further comprising a second metallic layer disposed adjacent to and in contact with the first metallic layer, the second metallic layer formed of copper and having substantially the same curvature of the first metallic layer, perimeter portions of the first and second layers extending over the at least one insulating layer of the semiconductor device.

11. The semiconductor device of claim 10, wherein the at least one insulating layer is a passivation layer.

12. The semiconductor device of claim 10, further comprising a third metallic layer disposed on the second metallic layer and having substantially the same curvature as the first and second metallic layers, and configured to receive the solder ball within its curvature.

13. The semiconductor device of claim 12, wherein the third metallic layer is formed of nickel.

14. The semiconductor device of claim 13, further comprising a solder bump formed over the third metallic layer and within it curvature, wherein electrical communication is established from the bonding pad, through the UBM structure, and to the solder bump.

15. The semiconductor device of claim 10, wherein the first metallic layer is about 1 micron in height.

16. The semiconductor device of claim 10, wherein the second metallic layer is about 5 microns in height.

17. A method for forming a semiconductor device, the method comprising:
providing a bonding pad associated with the semiconductor device and in direct electric contact with an integrated circuit;
forming at least one insulation layer over a perimeter of the bonding pad so as to leave a center portion of the bonding pad exposed;
depositing a tantalum layer over the at least one insulation layer and in direct contact with the bonding pad;
depositing a copper layer over and in direct contact with the tantalum layer, and so as to have substantially the same curvature as the tantalum layer;
depositing a third metallic layer over and in direct contact with the copper layer, and so as to have substantially the same curvature as the tantalum and copper layers; and
forming a solder bump in direct contact with and within the curvature of the third metallic layer.

18. The method of claim 17, wherein depositing at least one insulating layer comprises depositing a passivation layer.

19. The method of claim 18, wherein depositing at least one insulating layer further comprises depositing a polyimide layer over and in contact with the passivation layer.

20. The method of claim 17, wherein the third metallic layer is formed of nickel.
